(19) United States
(12) Patent Application Publication
(10) Pub. No.: US 2015/0021575 A1
(43) Pub. Date: Jan. 22, 2015

(54) INDOLOCARBAZOLE DERIVATIVE HAVING BIPYRIDINE UNIT AND ORGANIC ELECTROLUMINESCENCE DEVICE USING THE SAME

(71) Applicant: SAMSUNG DISPLAY CO., LTD., Yongin-City (JP)

(72) Inventor: Ichinori TAKADA, Yokohama (JP)

(21) Appl. No.: 14/331,812

(22) Filed: Jul. 15, 2014

(30) Foreign Application Priority Data
Jul. 17, 2013 (JP) 2013-148189

(51) Int. Cl. H01L 51/00

(52) U.S. Cl. CPC H01L 51/0058; H01L 51/0072; H01L 51/0067; H01L 51/0052; H01L 51/5056
USPC 257/40; 546/256

(57) ABSTRACT

An indolocarbazole derivative having a bipyridine derivative is represented by formula [Idc]ₐ-[L]_{b}-[E]_{c} where, [Idc] is a indolocarbazole group, represented by Formulae (A1) to (A6), as further defined in the specification, [L] is a single bond or an arylene group having 6 to 30 carbon atoms, and [E] is a bipyridine group represented by Formulae (B1) to (B6), as further defined in the specification.

### CROSS-REFERENCE TO RELATED APPLICATION

Japanese Patent Application No. 2013-148189, filed on Jul. 17, 2013, in the Japanese Patent Office, and entitled: “Indolocarbazole Derivative Having Bipyridine Unit and Organic Electroluminescence Device Using the Same,” is incorporated by reference herein in its entirety.

### BACKGROUND

1. Field

Embodiments relate to an indolocarbazole derivative having a bipyridine unit and an organic electroluminescence device using the same.

2. Description of the Related Art

In recent years, organic electroluminescence (EL) displays, which are one type of image display, have been actively developed. Unlike a liquid crystal display and the like, the organic EL display is a self-luminescent display that recombines holes and electrons injected from a positive electrode and a negative electrode in an emission layer to thus emit lights from a light-emitting material including an organic compound of the emission layer, thereby providing a display.

An example of an organic electroluminescence device (hereinafter referred to as an organic EL device) is an organic EL device, which may, for example, include a positive electrode, a hole transport layer disposed on the positive electrode, an emission layer disposed on the hole transport layer, an electron transport layer disposed on the emission layer, and a negative electrode disposed on the electron transport layer. Holes injected from the positive electrode are injected into the emission layer via the hole transport layer. Electrons are injected from the negative electrode, and then injected into the emission layer via the electron transport layer. The holes and the electrons injected into the emission layer are recombined to generate excitons within the emission layer. The organic EL device emits light by using light generated by the radiation and deactivation of the excitons.

### SUMMARY

Embodiments are directed to an indolocarbazole derivative including a bipyridine unit, the indolocarbazole derivative being represented by following Formula (1): [Idc]a-[L]b-[E]c (1) wherein: [Idc] is a indolocarbazole group selected from indolocarbazole groups represented by following Formulae (A1) to (A6),

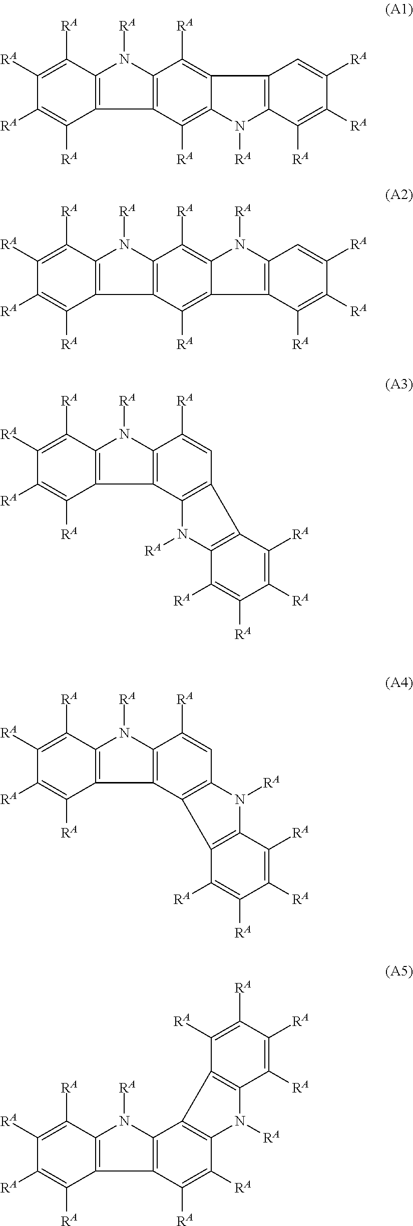

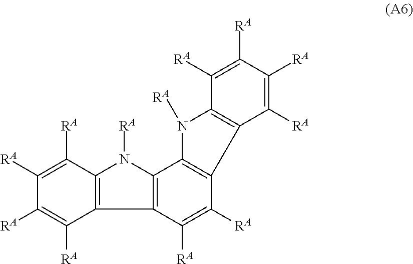

[L] is a single bond or an arylene group having 6 to 30 carbon atoms, and [E] is a bipyridine group selected from bipyridine groups represented by the following Formulae (B1) to (B6),

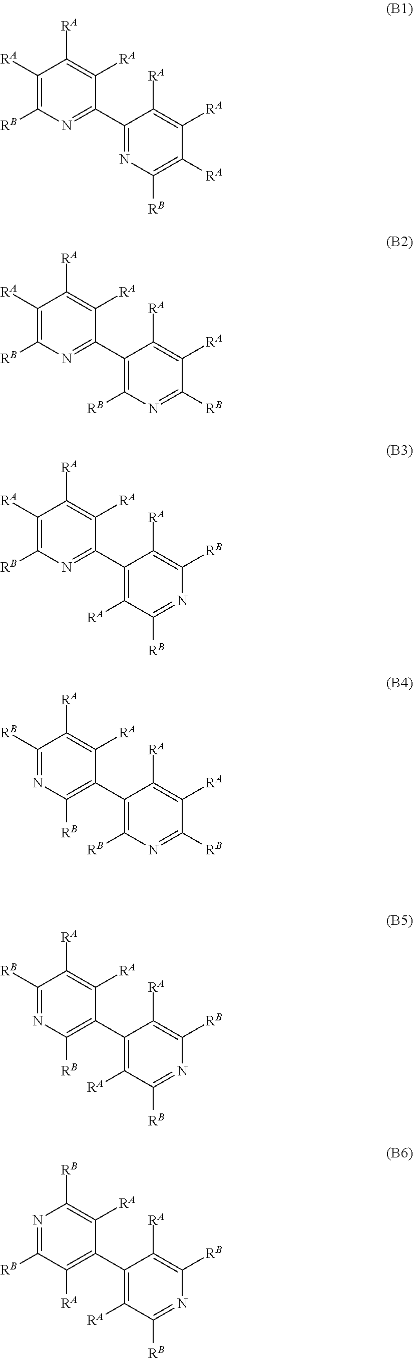

wherein, in Formula 1, a is 1, b is an integer from 0 to 3, c is an integer from 1 to 3, in Formulae (A1) to (A6) and (B1 to B6), each of R^{A} is independently an alkyl group having 1 to 10 carbon atoms, an aryl group having 6 to 30 carbon atoms, a nitrile group, a hydrogen atom or a halogen atom, and each of R^{B} is independently an alkyl group having 1 to 10 carbon atoms or an aryl group having 6 to 30 carbon atoms, provided that one of R^{A} in the selected indolocarbazole group and one of R^{B} in the selected bipyridine group represents a bonding site with L.

Embodiments are also directed to an organic electroluminescence device including the indolocarbazole derivative including the bipyridine unit, as describe above.

A molecular weight of the indolocarbazole derivative represented by Formula (1) may be less than or equal to 900.

The indolocarbazole derivative represented by Formula (1) may be included in a host material of an emission layer.

The indolocarbazole derivative represented by Formula (1) may be included in a stacking layer adjacent to an emission layer between the emission layer and a positive electrode.

The indolocarbazole derivative may be selected from the following Compounds 1 to 20:

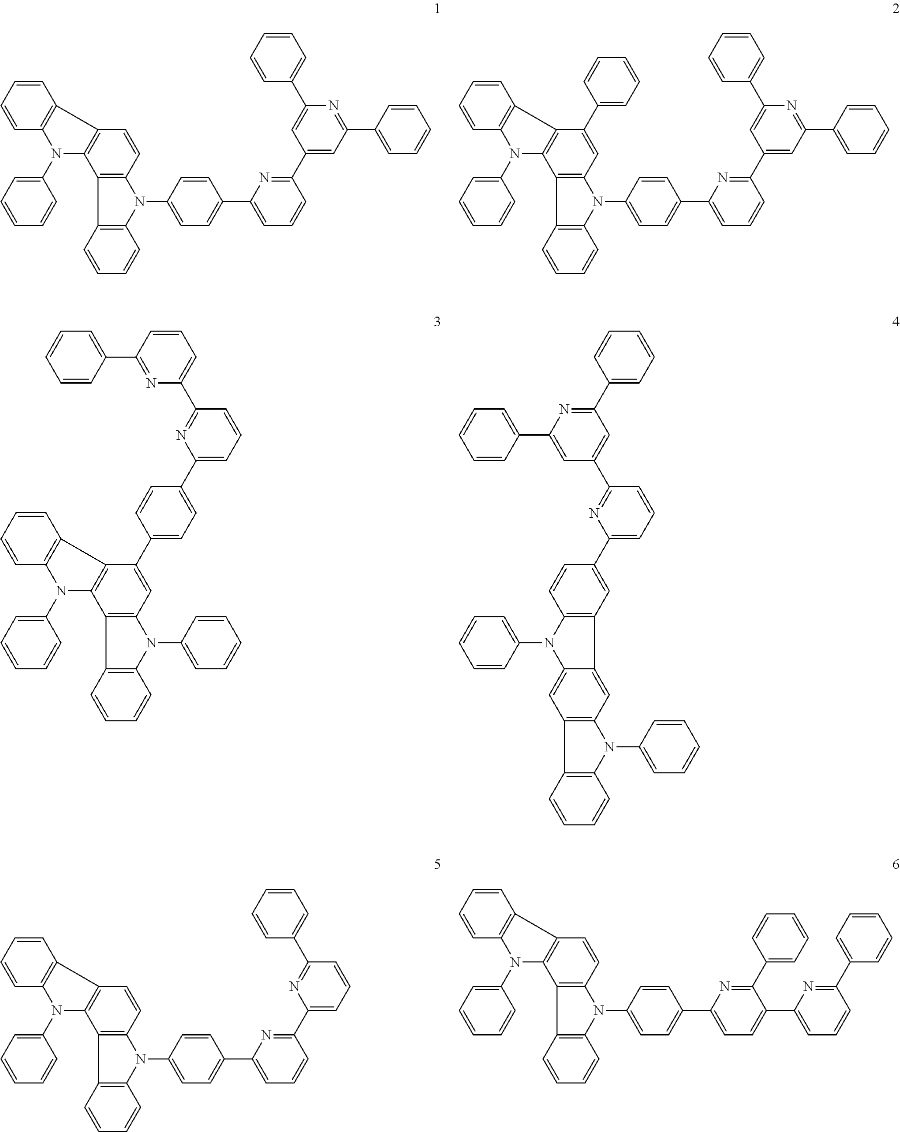

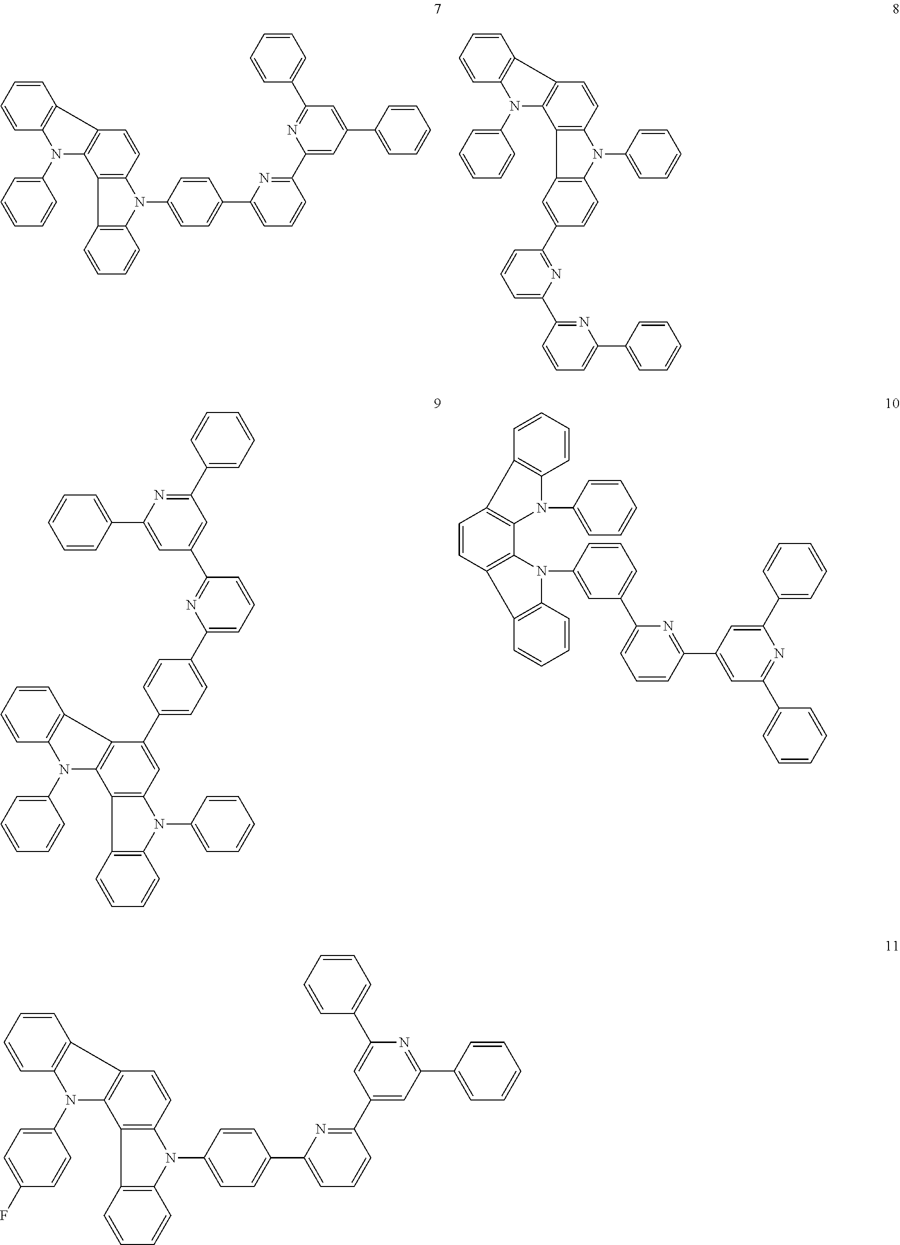

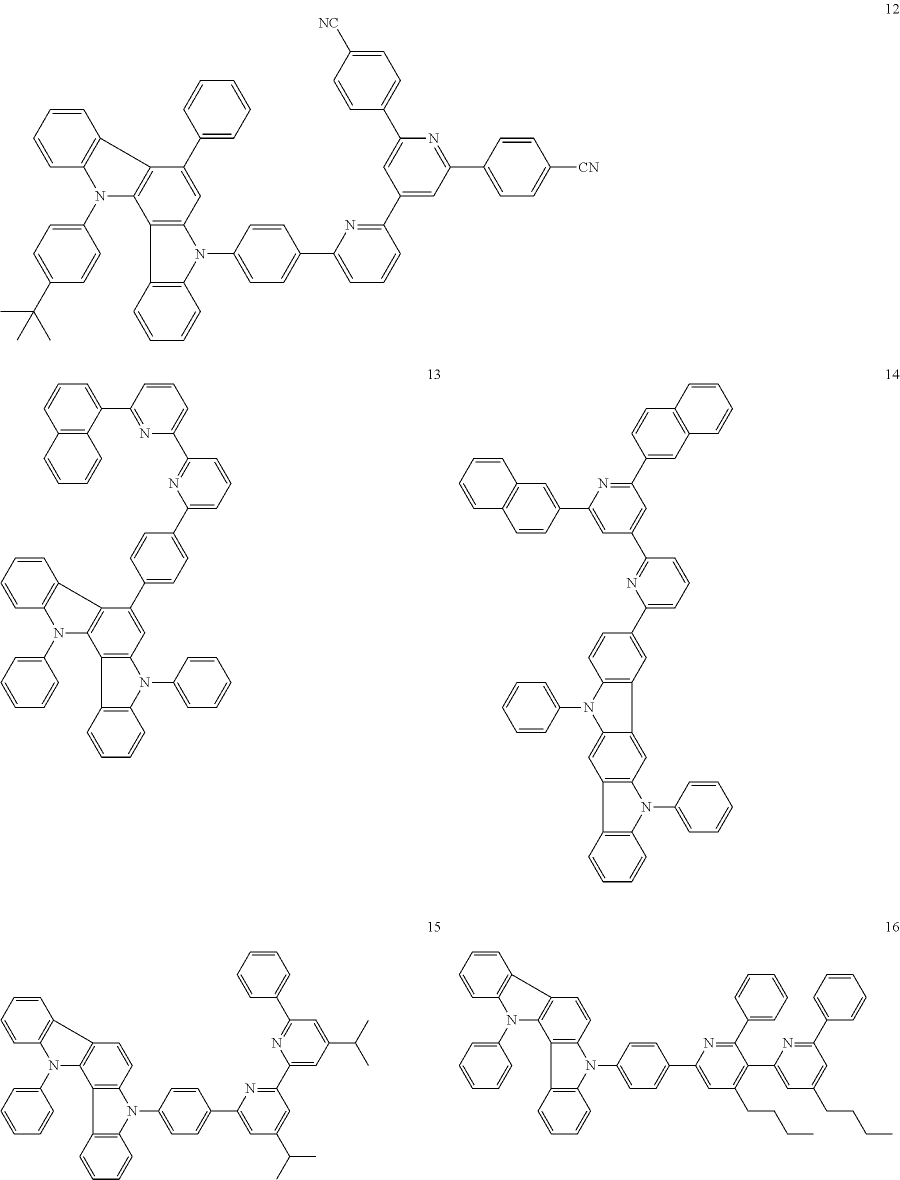

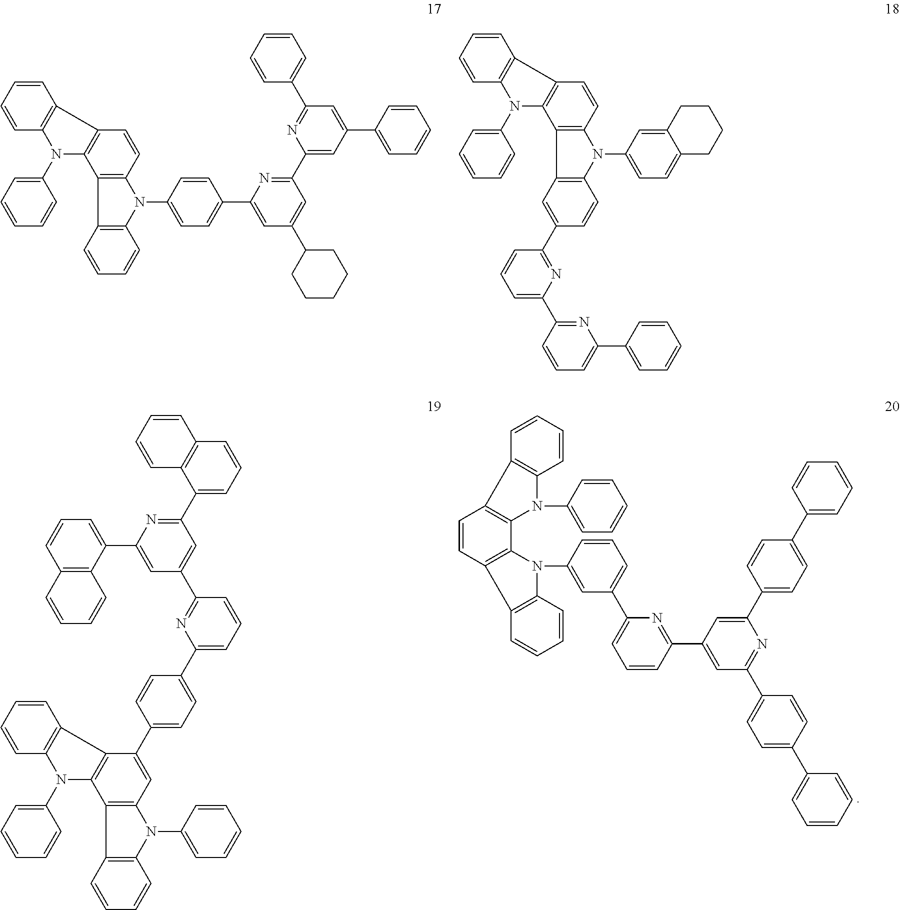

In the organic electroluminescence device, the indolocarbazole derivative including the bipyridine unit may be selected from the above Compounds 1 to 20.

### BRIEF DESCRIPTION OF THE DRAWINGS

Features will become apparent to those of skill in the art by describing in detail exemplary embodiments with reference to the attached drawings in which:

FIG. 1 illustrates the structure of an organic EL device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

Hereinafter, the indolocarbazole derivative having a bipyridine unit, and an organic EL device using the same will be explained.

An indolocarbazole derivative having a bipyridine unit according to embodiments has a structure represented by the following Formula (1).

[Formula (1)]

[Idc]ₐ-[L]_{b}-[E]_{c} (1)

In Formula (1), [Idc] is a indolocarbazole group selected from indolocarbazole groups represented by the following Formulae (A1) to (A6).

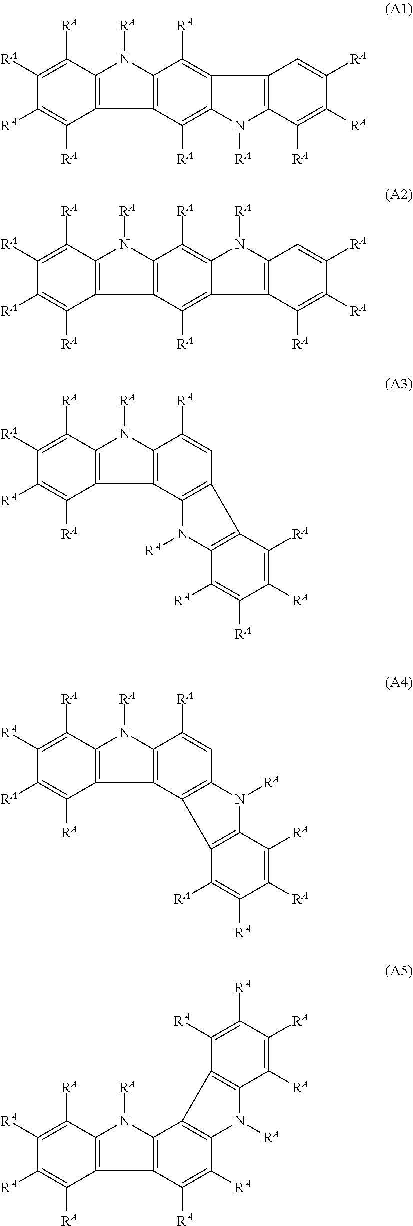

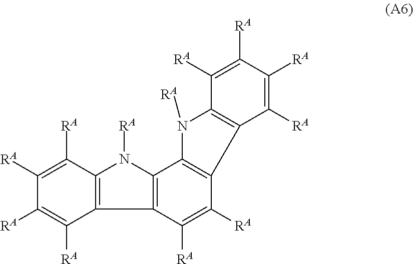

In Formula (1), [L] is a single bond or an arylene group having 6 to 30 carbon atoms, and [E] is a bipyridine group selected from the bipyridine groups represented by the following Formulae (B1) to (B6).

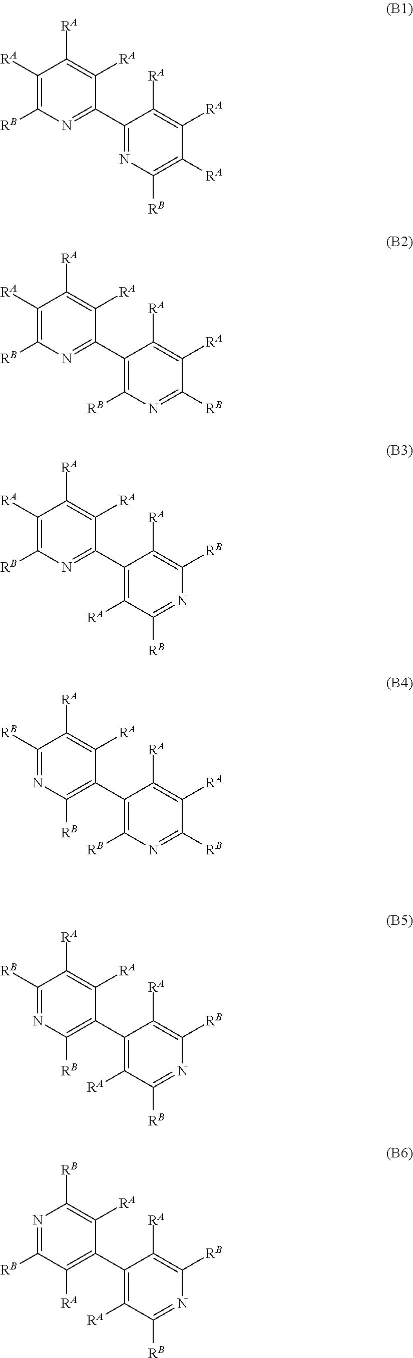

In Formula (1), a is 1, b is an integer from 0 to 3, and c is an integer from 1 to 3.

Here, in Formulae (A1) to (A6) and (B1) to (B6), each of R^{A} is independently an alkyl group having 1 to 10 carbon atoms, an aryl group having 6 to 30 carbon atoms, a nitrile group, a hydrogen atom or a halogen atom, and each of R^{B} is independently an alkyl group having 1 to 10 carbon atoms or an aryl group having 6 to 30 carbon atoms, provided that one of R^{A} in the selected indolocarbazole group and one of R^{B} in the selected bipyridine group represents a bonding site with L.

In the indolocarbazole derivative having a bipyridine unit represented by Formula (1) according to embodiments, the α-position of a nitrogen atom (N) of the bipyridine unit represented by Formulae (B1) to (B6) may be a bonding site with L or may be substituted with an alkyl group having 1 to 10 carbon atoms or an aryl group having 6 to 30 carbon atoms. Through the combination of the α-position of the nitrogen atom (N) of the bipyridine unit with L, or through the blocking by a substituent, the deterioration or the agglomeration of a material may be restrained. As a result, a stable organic thin film including the indolocarbazole derivative having a bipyridine unit may be formed, and the long life of the organic EL device may be realized.

In addition, the indolocarbazole derivative having a bipyridine unit represented by Formula (1) according to embodiments includes a bipyridine unit and an indolocarbazole unit, and may adjust the balance of charges in an organic EL device and accomplish high efficiency.

The indolocarbazole derivative having a bipyridine unit may have a molecular weight of less than or equal to 900. When the molecular weight is less than or equal to 900, the thermal decomposition of a material may be restrained while forming an organic thin film including the indolocarbazole derivative having a bipyridine unit by a deposition method in the manufacturing process of an organic EL device, and a stable organic thin film may be formed.

As examples of the indolocarbazole derivative having a bipyridine unit according to embodiments, the following Compounds 1 to 20 may be illustrated.

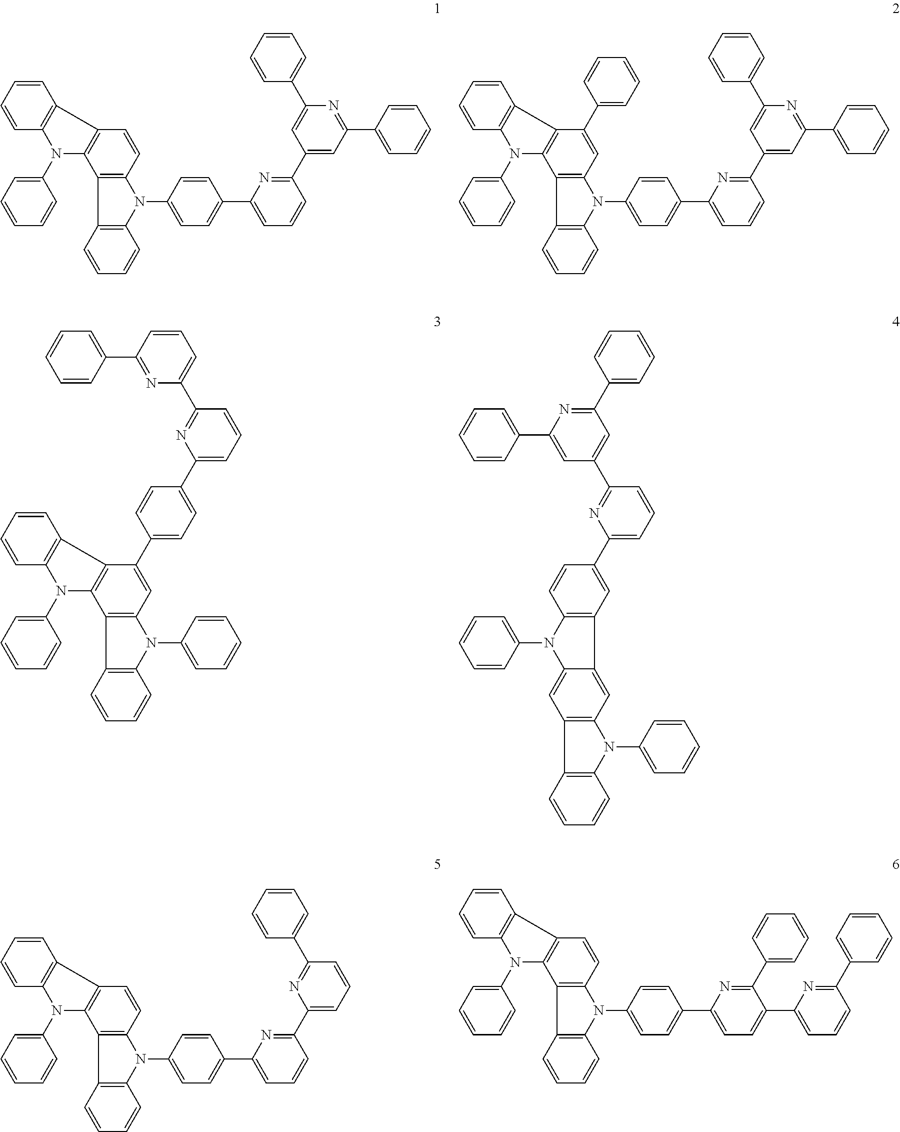

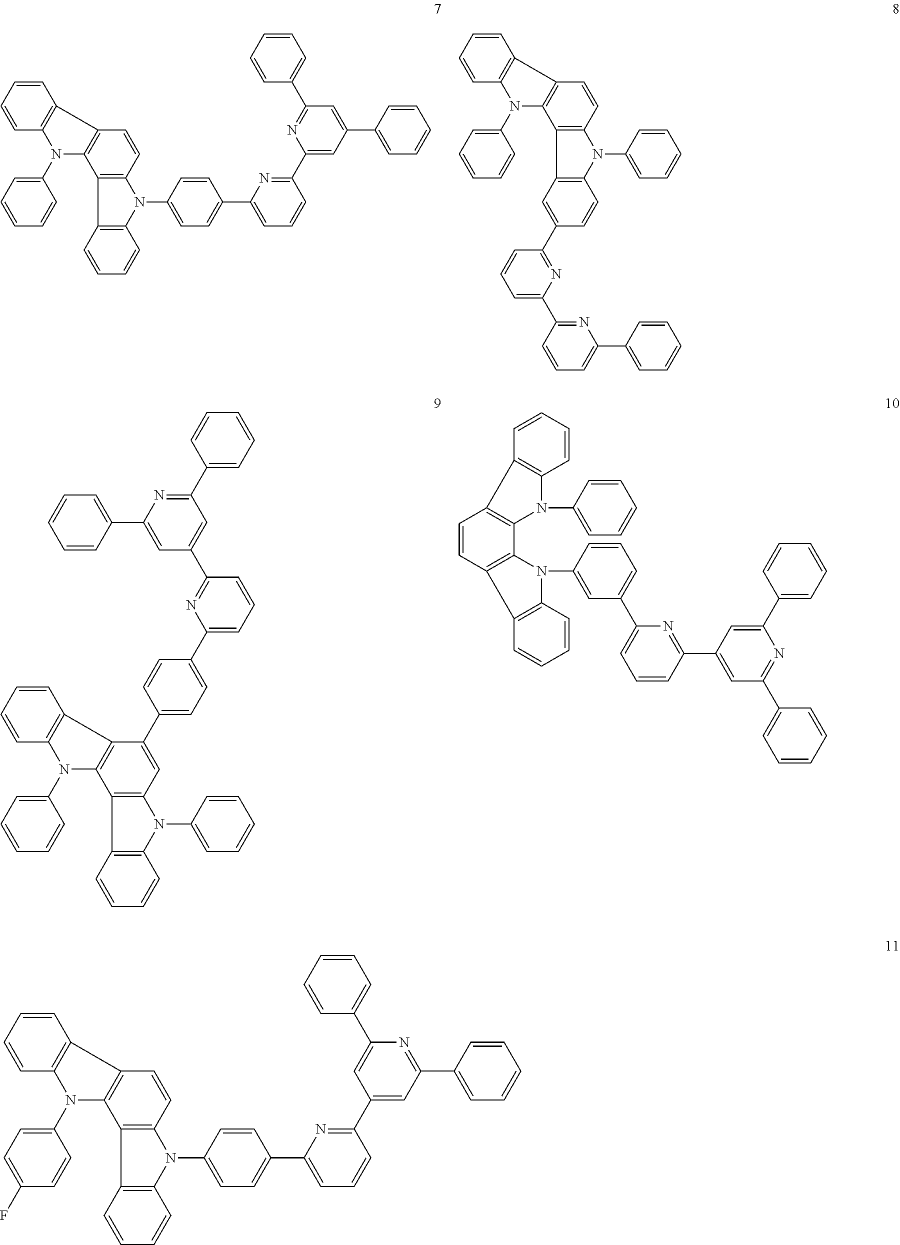

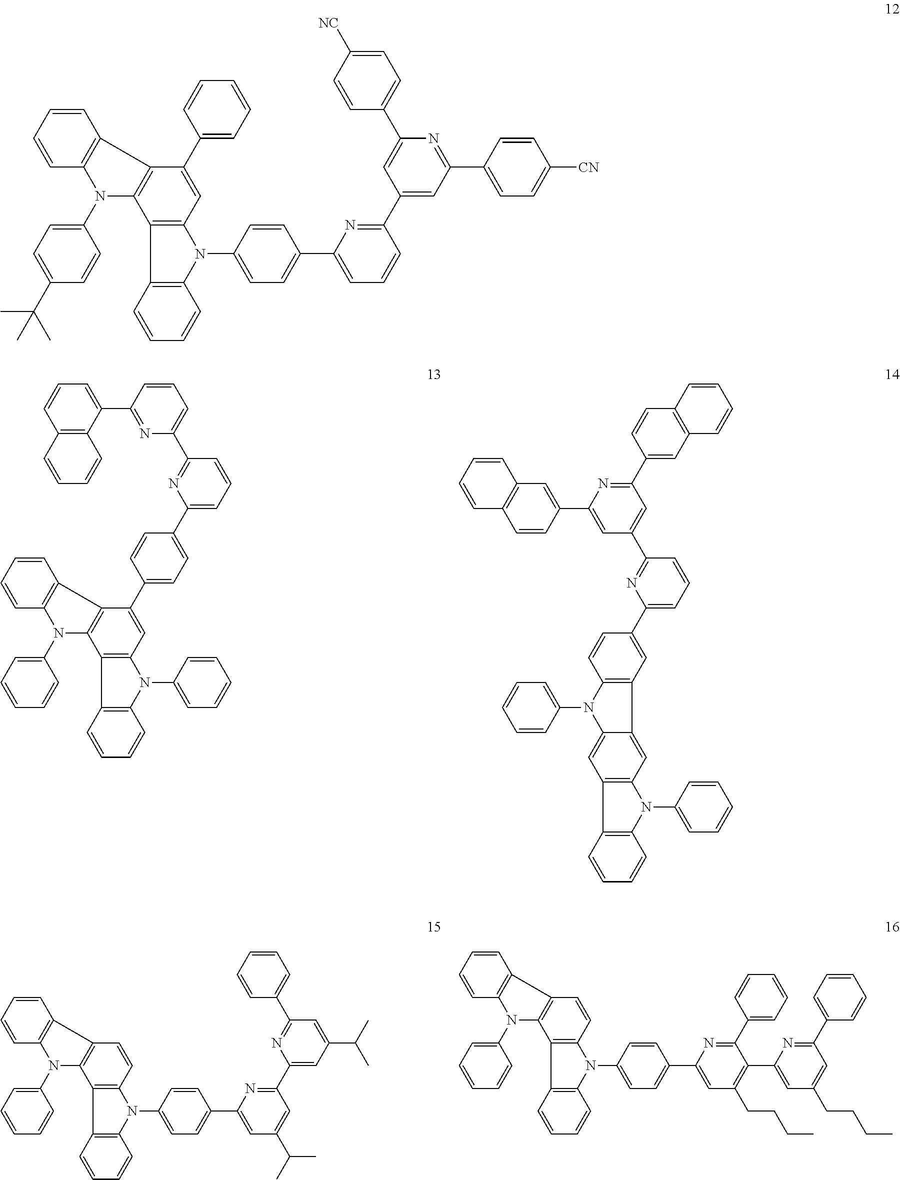

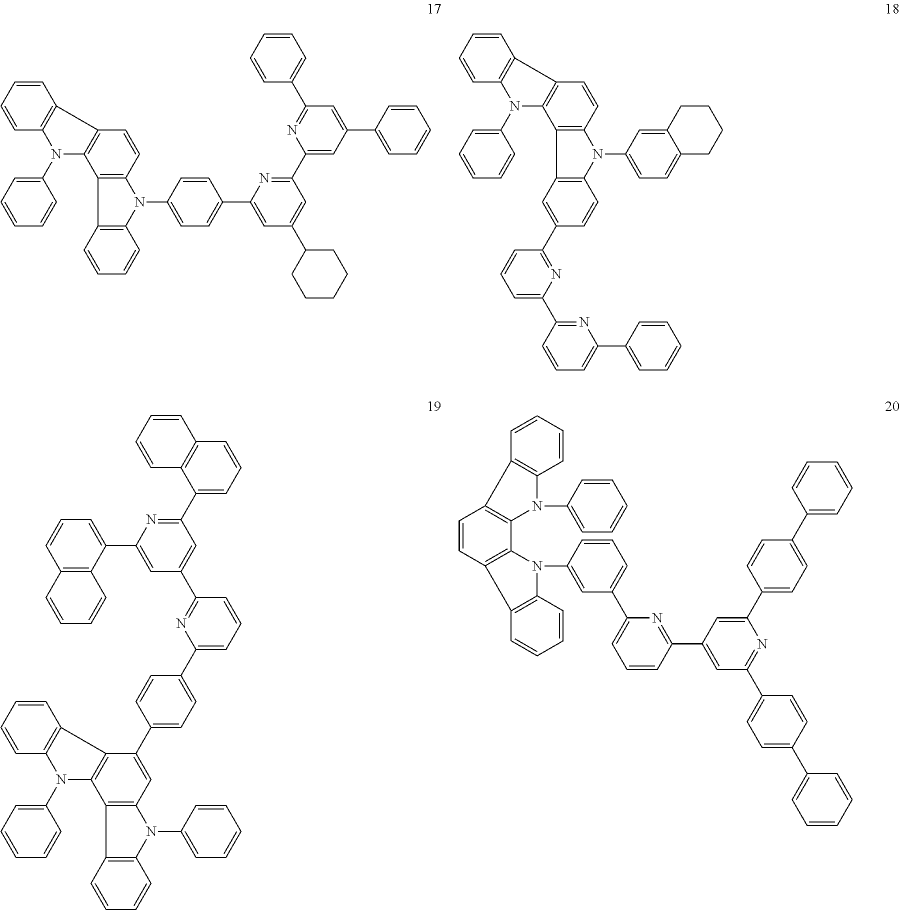

In the indolocarbazole derivative having a bipyridine unit according to embodiments, 8 or more atoms may be present between the nitrogen atom (N) of the indolocarbazole nearest to the bipyridine unit and the nitrogen atom (N) of the bipyridine unit farthest from the nitrogen atom (N) of the indolocarbazole by inserting a connecting group [L]. In the case that hetero atoms are concentrated in a compound including hetero atoms such as the nitrogen atom (N), the stability of the compound may be deteriorated. In the indolocarbazole derivative having a bipyridine unit according to embodiments, 8 or more atoms may be disposed between the nitrogen atom (N) of the indolocarbazole nearest to the bipyridine unit and the nitrogen atom (N) of the bipyridine unit farthest from the nitrogen atom (N) of the indolocarbazole. The concentration of the hetero atoms in the indolocarbazole derivative having a bipyridine unit may be avoided, and the hetero atoms may be dispersed in the molecule. Thus, the stability of a material may be favorably maintained, and the long life of the organic EL device may be attained.

For example, as described below, in Compound 1, which is an example of the indolocarbazole derivative having a bipyridine unit according to embodiments, 10 atoms are present between the nitrogen atom (N) of the indolocarbazole nearest to the bipyridine unit and the nitrogen atom (N) of the bipyridine unit farthest from the nitrogen atom (N) of the indolocarbazole. In Compound 10, 9 atoms are present between the nitrogen atom (N) of the indolocarbazole nearest to the bipyridine unit and the nitrogen atom (N) of the bipyridine unit farthest from the nitrogen atom (N) of the indolocarbazole. In Compound 15, 8 atoms are present between the nitrogen atom (N) of the indolocarbazole nearest to the bipyridine unit and the nitrogen atom (N) of the bipyridine unit farthest from the nitrogen atom (N) of the indolocarbazole. For example, the nitrogen atom (N) of the indolocarbazole nearest to the bipyridine unit and the nitrogen atom (N) of the bipyridine unit farthest from the nitrogen atom (N) of the indolocarbazole in the following Compound 1, Compound 10 and Compound 15, are illustrated below by circular broken lines.

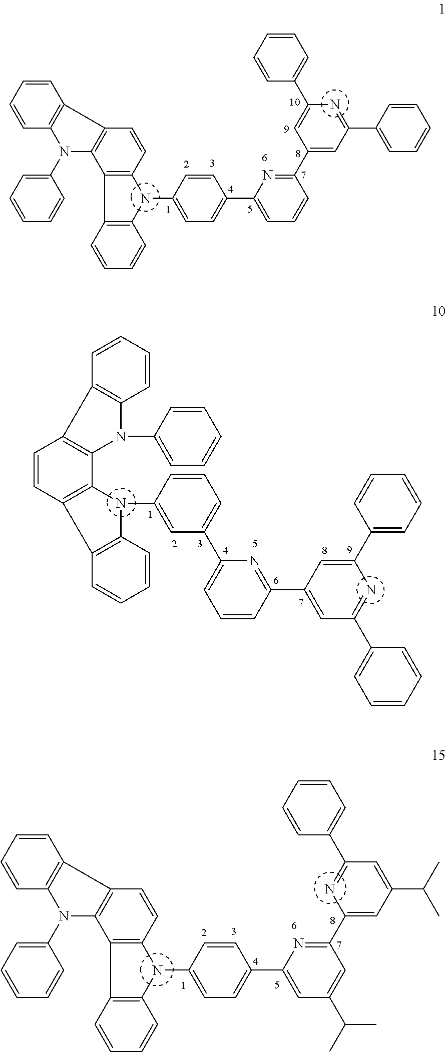 [SMILES: c1ccc(-c2cc(-c3cccc(-c4ccc(-n5c6ccccc6c6c5ccc5c7ccccc7n(-c7ccccc7)c56)cc4)n3)cc(-c3ccccc3)n2)cc1 ; c1ccc(-c2cc(-c3cccc(-c4cccc(-n5c6ccccc6c6ccc7c8ccccc8n(-c8ccccc8)c7c65)c4)n3)cc(-c3ccccc3)n2)cc1 ; CC(C)c1cc(-c2ccccc2)nc(-c2cc(C(C)C)cc(-c3ccc(-n4c5ccccc5c5c4ccc4c6ccccc6n(-c6ccccc6)c45)cc3)n2)c1]

The indolocarbazole derivative having a bipyridine unit according to embodiments may be appropriately used as a host material of a phosphorescent emission layer of an organic EL device. By using the indolocarbazole derivative having a bipyridine unit according to embodiments as the host material of the emission layer, the increase of the T1 level may become possible, and the long life of the organic EL device may be realized.

In other implementations, the indolocarbazole derivative having a bipyridine unit according to embodiments may be used as a material of a stacking layer adjacent to the phosphorescent emission layer of the organic EL device toward a positive electrode. For example, the indolocarbazole derivative having a bipyridine unit according to embodiments may be included in a hole transport layer or a hole injection layer adjacent to the phosphorescent emission layer of the organic EL device. For example, the indolocarbazole derivative having a bipyridine unit according to embodiments may be included at the boundary between the emission layer with the hole transport layer or the hole injection layer. When the indolocarbazole derivative having a bipyridine unit according to embodiments is included at the boundary of the emission layer and the hole transport layer or the hole injection layer, an invasion of energy into the hole transport layer or the hole injection layer may be blocked due to the recombination of the holes and the electrons in the emission layer. Through the recombination of the holes and the electrons in the emission layer, an invasion of the energy into the hole transport layer or the hole injection layer may be prevented, and by trapping the generated energy in the emission layer, a long life of the organic EL device may be provided.

The indolocarbazole derivative having a bipyridine unit according to embodiments may be synthesized by a method among the following general synthetic Processes 1 to 8. In the following synthetic processes, Idc represents [Idc] in Formula (1), E represents [E] in Formula (1), and L represents [L] in Formula (1).

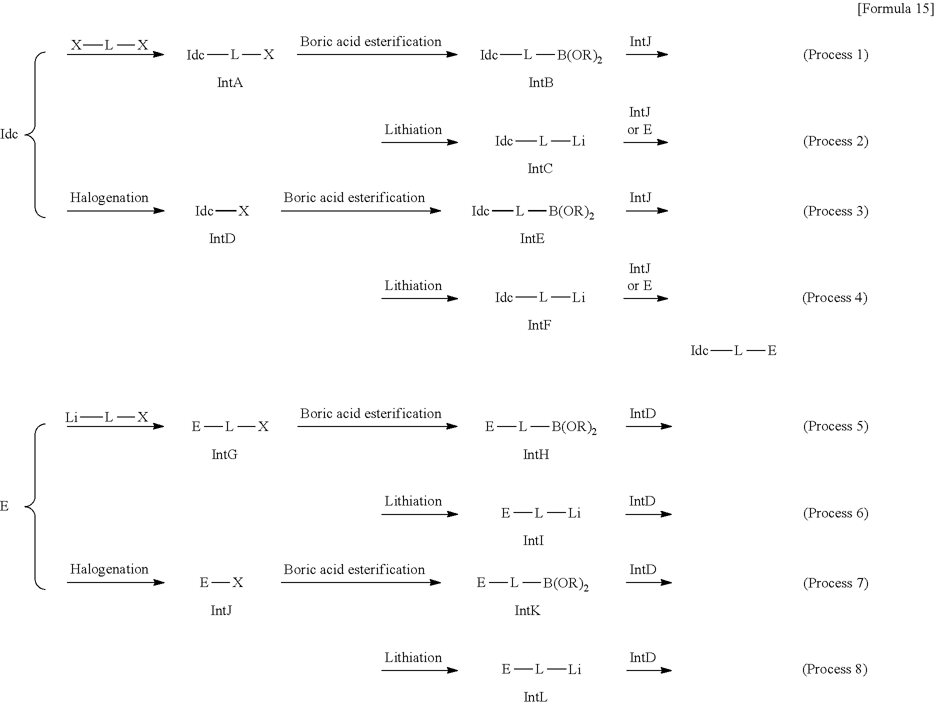

In the above synthetic processes, X is a halogen atom, IntA, IntD, IntG, and IntJ may be commercially available materials, and a suitable synthetic process may be applied for the synthesis. For example, Compound 1 may be synthesized by synthesizing IntJ by another known process, and then performing Process 1. In addition, for example, Compound 5 may be synthesized by using phenylbiquinoline as E through Process 2.

The above-described synthetic process of Compound 1 will be explained in more detail. In addition, the following method is only an embodiment and may be synthesized by other methods.

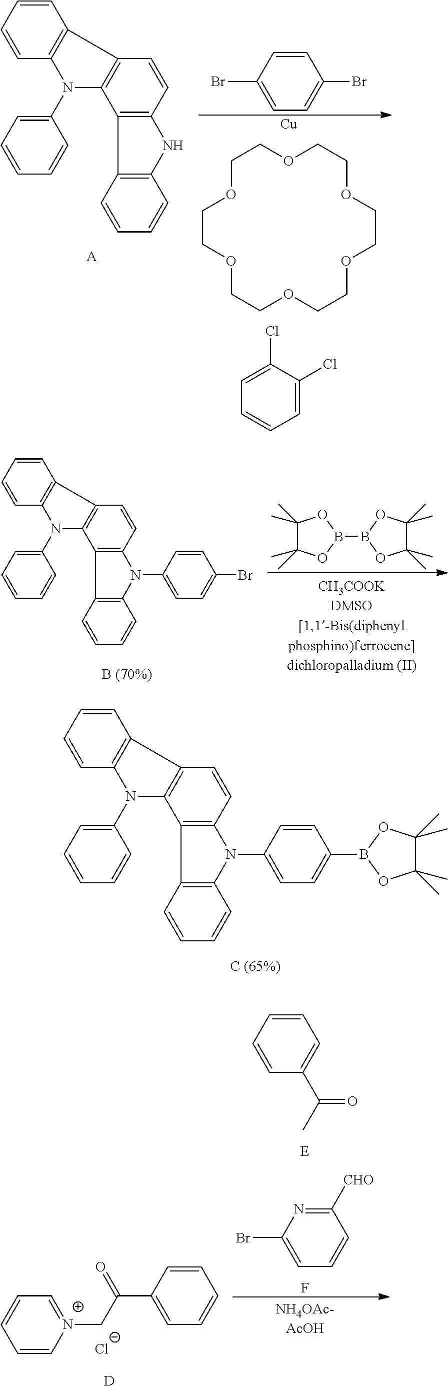

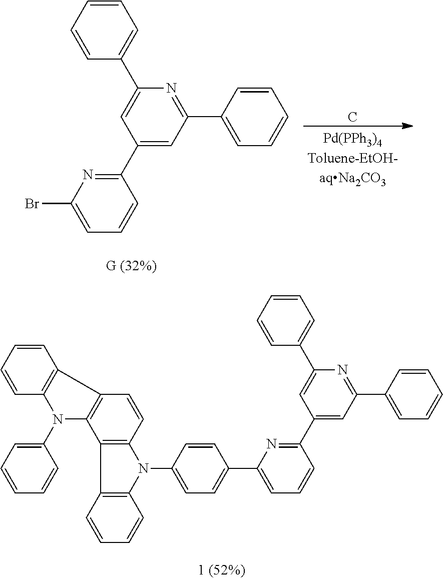

### Synthesis of Compound 1

### Synthetic Example

An indolocarbazole A (2.00 g, 6.20 mmol), 1,4-dibromobenzene (14.6 g, 62.0 mmol), a copper powder (3.15 g, 49.6 mmol), and 18-crown-6 (860 mg, 3.72 mmol) were dissolved in o-dichlorobenzene (20 ml) and stirred at 190° C. for 14 hours. After cooling, the reactant was inserted in hexane, and precipitations were extracted. Solids were washed with chloroform, the washed solution was concentrated, and the residue thus obtained was separated by silica gel chromatography to obtain a bromo body (B 2.12 g, 4.34 mmol) in a yield of 70%.

The bromo body (B 1.54 g, 3.17 mmol), bis(pinacolato) diborane (1.61 g, 6.33 mmol), a [1,1′-bis(diphenylphosphino)ferrocene]dichloropalladium (II)dichloromethane complex (130 mg, 0.160 mmol) and potassium acetate (930 mg, 9.50 mmol) were dissolved in dimethyl sulfoxide (50 ml) and stirred at 90° C. for 8 hours. The reaction mixture was inserted into water and extracted with chloroform. An organic layer was washed with saturated saline and dried with anhydrous magnesium sulfate. The organic layer was concentrated, and the residue thus obtained was separated by silica gel chromatography to obtain boric acid pinacol ester C (1.10 g, 2.06 mmol) in a yield of 65%.

A pyridinium salt D (377 mg, 1.61 mmol), acetophenone E (161 mg, 1.34 mmol), a bromopyridine F (250 mg, 1.34 mmol), and ammonium acetate (4.14 g, 53.8 mmol) were dissolved in 3 mL of acetic acid, and microwaves (130 W, 100° C., 5 minutes) were irradiated. The reaction mixture was added into water and extracted with chloroform. An organic layer was washed with saturated saline and dried with anhydrous magnesium sulfate. The organic layer was concentrated, and the residue thus obtained was separated by silica gel chromatography to obtain a bromobipyridine G (167 mg, 0.430 mol) in a yield of 32%.

Boric acid pinacol ester C (1.58 g, 2.96 mmol), the bromobipyridine G (1.15 g, 2.96 mmol) and tetrakistriphenylphosphinepalladium(0) (171 mg, 0.148 mmol) were dissolved in a mixture solution of toluene (80 mL), ethanol (80 mL) and 2M-sodium carbonate (80 mL) and stirred for 12 hours. The reaction mixture was extracted with toluene, and an organic layer was washed with saturated saline and dried with anhydrous magnesium sulfate. The organic layer was concentrated, and the residue thus obtained was separated by silica gel chromatography to obtain Compound 1 (1.10 g, 1.54 mmol) in a yield of 52%.

Other indolocarbazole derivatives having a bipyridine unit may also be synthesized by combining known chemical reactions as illustrated in Processes 1 to 8.

Organic EL device

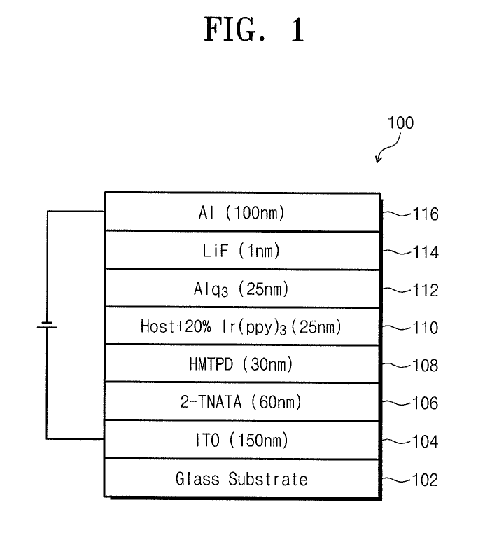

An organic EL device using the indolocarbazole derivative having a bipyridine unit according to embodiments as a host material of an emission layer of an organic EL device will be explained referring to FIG. 1.

FIG. 1 illustrates a schematic diagram depicting the configuration of an organic EL device 100 according to an embodiment. The organic EL device 100 may include, for example, a substrate 102, a positive electrode 104, a hole injection layer 106, a hole transport layer 108, an emission layer 110, an electron transport layer 112, an electron injection layer 114 and a negative electrode 116. Materials and thicknesses for each of these layers are provided in FIG. 1 as examples.

The substrate 102 may be a transparent glass substrate, a semiconductor substrate formed by using silicon, etc., or a flexible substrate. The positive electrode 104, disposed on the substrate 102, may be formed by using indium tin oxide (ITO). In other implementations, the positive electrode 104 may be formed by using indium zinc oxide (IZO), etc. The hole injection layer 106, disposed on the positive electrode 104, may include 4,4′,4″-tris(N-2-naphthyl)-N-phenylamino)-triphenylamine (2-TNATA), etc. The hole transport layer 108, disposed on the hole injection layer 106, may is formed by using, for example, 4,4′-bis[N,N′-(3-tolyl)amino]-3,3′-dimethylbiphenyl (HMTPD), etc. The emission layer 110, disposed on the hole transport layer 108, may be formed by doping an Ir complex such as Ir(ppy)₃tris(2-phenylpyridinato) iridium(III), etc. in a host material including the indolocarbazole derivative having a bipyridine unit according to embodiments. The electron transport layer 112, disposed on the emission layer 110, may be formed by using tris(8-hydroxyquinolinato) aluminum (Alq₃). The electron injection layer 114, disposed on the electron transport layer 112, may be formed by using, for example, a material including lithium fluoride (LiF). The negative electrode 116, disposed on the electron injection layer 114, may be formed by using a metal such as Al. In other implementations, the negative electrode 116 may be formed by using a transparent material such as ITO or IZO. The above-described layers and electrodes may be formed by selecting an appropriate layer forming method such as vacuum deposition, sputtering, various coatings, etc.

In the organic EL device 100 according to this embodiment, the indolocarbazole derivative having a bipyridine unit according to embodiments may be used as the host material of the emission layer of the organic EL device for realizing the long life of the organic EL device 100.

In other implementations, the indolocarbazole derivative having a bipyridine unit according to embodiments may be used as the material of the hole transport layer 108 adjacent to the emission layer. By using the indolocarbazole derivative having a bipyridine unit according to embodiments as the material of a stacking layer adjacent to the emission layer of the organic EL device, the long life of the organic EL device 100 may also be realized. When the hole transport layer 108 is omitted in the organic EL device 100, the indolocarbazole derivative having a bipyridine unit according to embodiments may be used as the material of the hole injection layer 106 adjacent to the emission layer.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Examples

Organic EL devices were manufactured by using the above Compound 1 and Compound 10, which are indolocarbazole derivatives having a bipyridine unit, as a host material of an emission layer. In this embodiment, the substrate 102 was formed by using a transparent glass substrate, the positive electrode 104 was formed using ITO to a thickness of about 150 nm, the hole injection layer 106 having a thickness of about 60 nm was formed by using 2-TNATA, the hole transport layer 108 was formed using HMTPD to a thickness of 30 nm, the emission layer 110 was formed by doping about 20% Ir(ppy)₃ in Compound 1 or Compound 10 to a thickness of about 25 nm, the electron transport layer 112 was formed using Alq₃ to a thickness of about 25 nm, the electron injection layer 114 was formed using LiF to a thickness of about 1 nm, and the negative electrode 116 was formed using Al to a thickness of about 100 nm. An organic EL device manufactured by using Compound 1 as the host material of the emission layer 110 corresponds to Example 1, and an organic EL device manufactured by using Compound 10 as the host material of the emission layer 110 corresponds to Example 2.

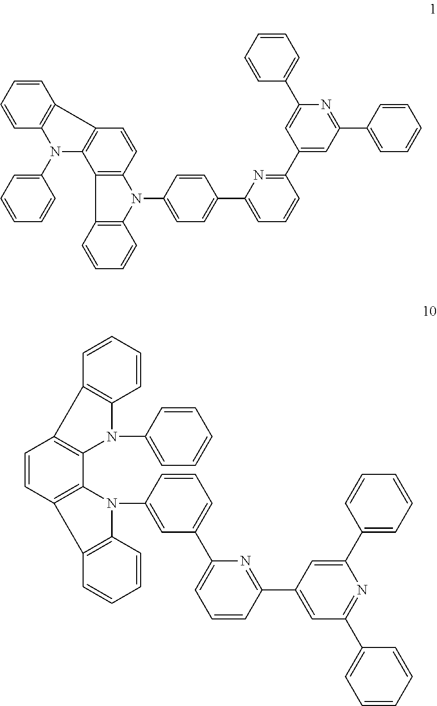 [SMILES: c1ccc(-c2cc(-c3cccc(-c4ccc(-n5c6ccccc6c6c5ccc5c7ccccc7n(-c7ccccc7)c56)cc4)n3)cc(-c3ccccc3)n2)cc1 ; c1ccc(-c2cc(-c3cccc(-c4cccc(-n5c6ccccc6c6ccc7c8ccccc8n(-c8ccccc8)c7c65)c4)n3)cc(-c3ccccc3)n2)cc1]

In addition, as comparative examples, organic EL devices were manufactured by using the following Comparative Compound 1 and Comparative Compound 2 as the host materials of the emission layer 110. The organic EL device manufactured by using Comparative Compound 1 as the host material of the emission layer 110 corresponds to Comparative Example 1, and the organic EL device manufactured by using Comparative Compound 2 as the host material of the emission layer 110 corresponds to Comparative Example 2. In Comparative Examples 1 and 2, the configuration of each layer is the same as that in Examples 1 and 2 except for using the compounds used as the host materials of the emission layer 110.

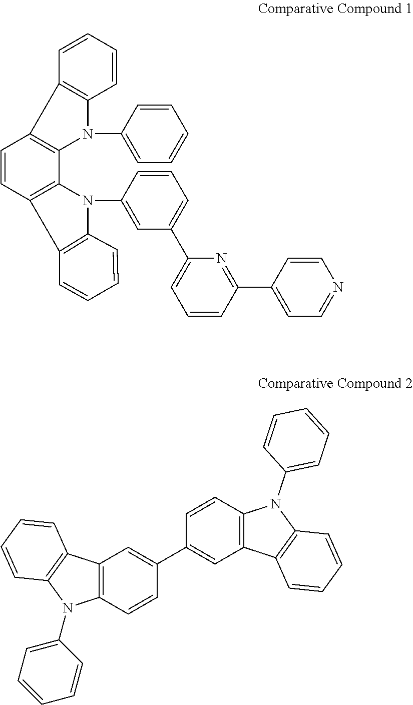 [SMILES: c1ccc(-n2c3ccccc3c3ccc4c5ccccc5n(-c5cccc(-c6cccc(-c7ccncc7)n6)c5)c4c32)cc1 ; c1ccc(-n2c3ccccc3c3cc(-c4ccc5c(c4)c4ccccc4n5-c4ccccc4)ccc32)cc1]

With respect to the organic EL devices according to Examples 1 and 2 and Comparative Examples 1 and 2, the emission efficiency and the life of the devices were measured with current density of 10 mA/cm², and half life of 1,000 cd/m². The results are illustrated in the following Table 1.

TABLE 1

| | Host material | Current | | Emission | Life |
|---|---|---|---|---|---|
| | in emission | density | Voltage | efficiency | LT50 |
| Device | layer | (mA/cm²) | (V) | (cd/A) | (h) |
| Example 1 | Compound 1 | 10 | 4.7 | 34.5 | 3300 |
| Example 2 | Compound 2 | 10 | 4.9 | 32.9 | 2800 |
| Comparative | Comparative | 10 | 5.1 | 33.1 | 900 |
| Example 1 | Compound 1 | | | | |
| Comparative | Comparative | 10 | 5.5 | 28.7 | 1100 |
| Example 2 | Compound 2 | | | | |

As shown in Table 1, the life of the organic EL devices manufactured by using Compound 1 and Compound 10, which are the indolocarbazole derivatives having a bipyridine unit according to Examples 1 and 2 was found to be longer when compared the life of the organic EL devices manufactured by using Comparative Examples 1 and 2.

In the above embodiments, the indolocarbazole derivative having a bipyridine unit according to embodiments was used as the material of a passive type organic EL device. In other implementations, the indolocarbazole derivative having a bipyridine unit may be used as the material of an active type organic EL device, and the long life of the active type organic EL device may also be realized.

The organic EL device using the indolocarbazole derivative having a bipyridine unit as the material may be used in an organic EL display apparatus or a lighting installation.

By way of summation and review, in the application of the organic EL device to a display apparatus, high efficiency or long life of the organic EL device, and materials to realize such, are desirable.

A phosphorescent emission material that emits light from a triplet excited state may be used in an emission layer of an organic EL device. As the phosphorescent emission material, a metal complex of a heavy atom such as platinum, rhodium, and ruthenium including iridium may be used. Other materials may be obtained through diverse combinations of a central metal with a ligand. A indolocarbazole compound may be used as a host material included in an emission layer of an organic EL device with a phosphorescent emission material.

Embodiments relate to an indolocarbazole derivative having a bipyridine unit providing a long life of an organic electroluminescence device when used as a host material of a phosphorescent emission layer of the organic electroluminescence device or when used in a stacking layer adjacent to the emission layer of the organic EL device toward the positive electrode.

In addition, when the molecular weight of the indolocarbazole derivative having a bipyridine unit according to an embodiment is less than or equal to 900, thermal decomposition during deposition may be restrained during manufacturing an organic EL device.

Example embodiments have been disclosed herein, and although specific term's are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. An indolocarbazole derivative including a bipyridine unit, the indolocarbazole derivative being represented by following Formula (1):
[Formula (1)]
[Idc]ₐ-[L]_{b}-[E]_{c} (1)
wherein:
[Idc] is a indolocarbazole group selected from the indolocarbazole groups represented by following Formulae (A1) to (A6), 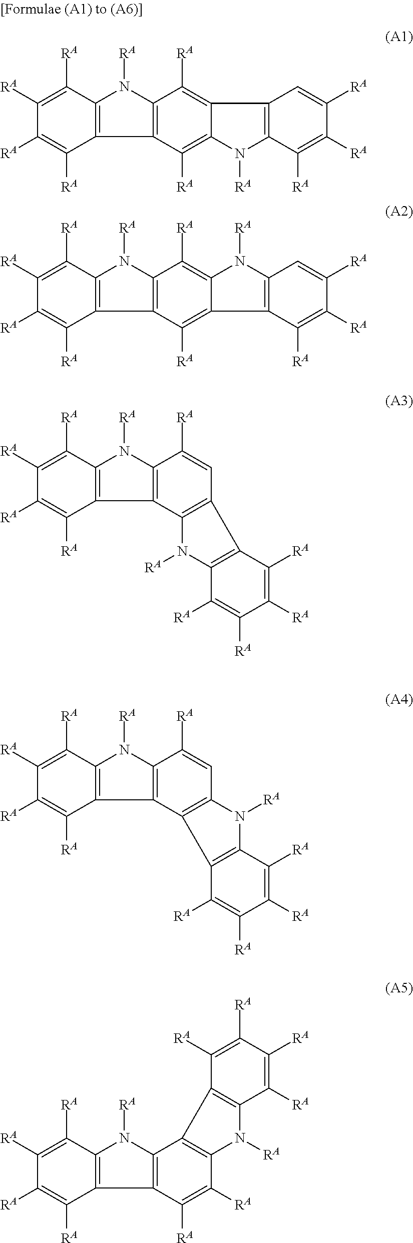 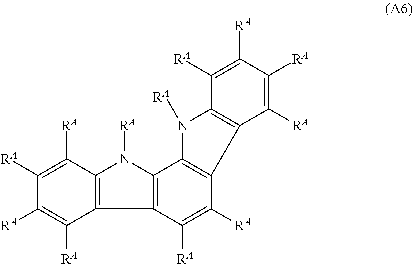
[L] is a single bond or an arylene group having 6 to 30 carbon atoms, and
[E] is a bipyridine group selected from the bipyridine groups represented by the following Formulae (B1) to (B6), 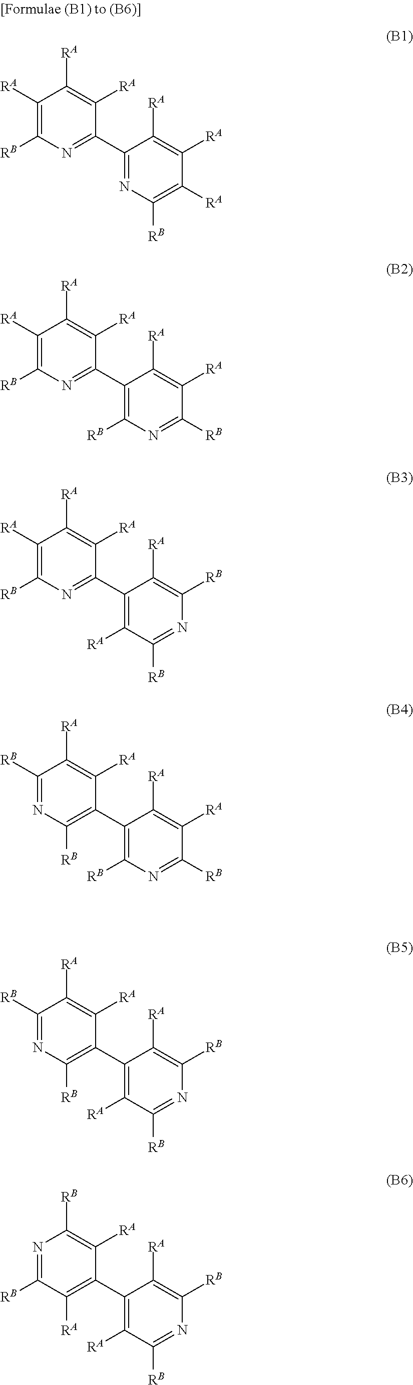
wherein, in Formula 1, a is 1, b is an integer from 0 to 3, c is an integer from 1 to 3,
in Formulae (A1) to (A6) and (B1 to B6), each of R^{A} is independently an alkyl group having 1 to 10 carbon atoms, an aryl group having 6 to 30 carbon atoms, a nitrile group, a hydrogen atom or a halogen atom, and each of R^{B} is independently an alkyl group having 1 to 10 carbon atoms or an aryl group having 6 to 30 carbon atoms, provided that one of R^{A} in the selected indolocarbazole group and one of R^{B} in the selected bipyridine group represents a bonding site with L.

2. An organic electroluminescence device, comprising an indolocarbazole derivative including a bipyridine unit, the indolocarbazole derivative being represented by following Formula (1):
[Formula (1)]
[Idc]ₐ[L]_{b}-[E]_{c} (1)
wherein:
[Idc] is a indolocarbazole group selected from indolocarbazole groups represented by following Formulae (A1) to (A6), 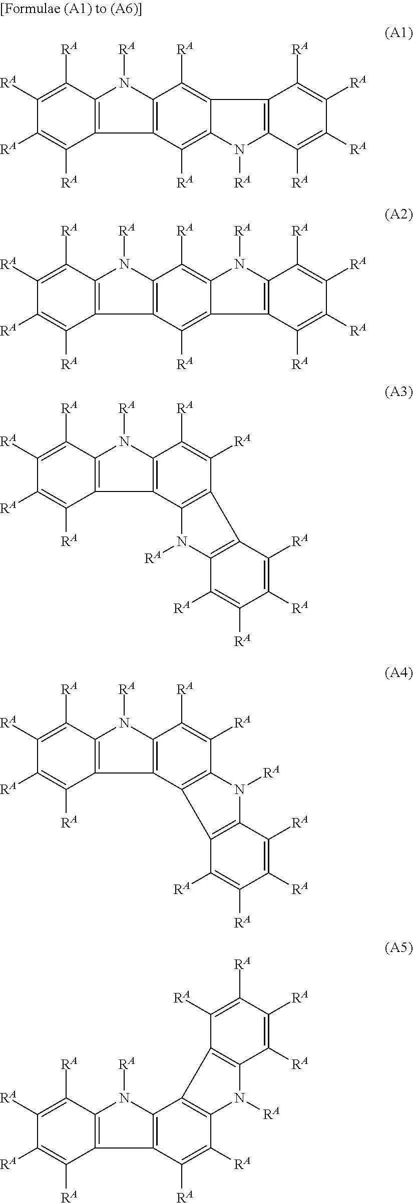 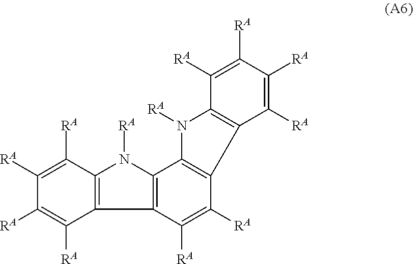
[L] is a single bond or an arylene group having 6 to 30 carbon atoms, and
[E] is a bipyridine group selected from bipyridine groups represented by the following Formulae (B1) to (B6), 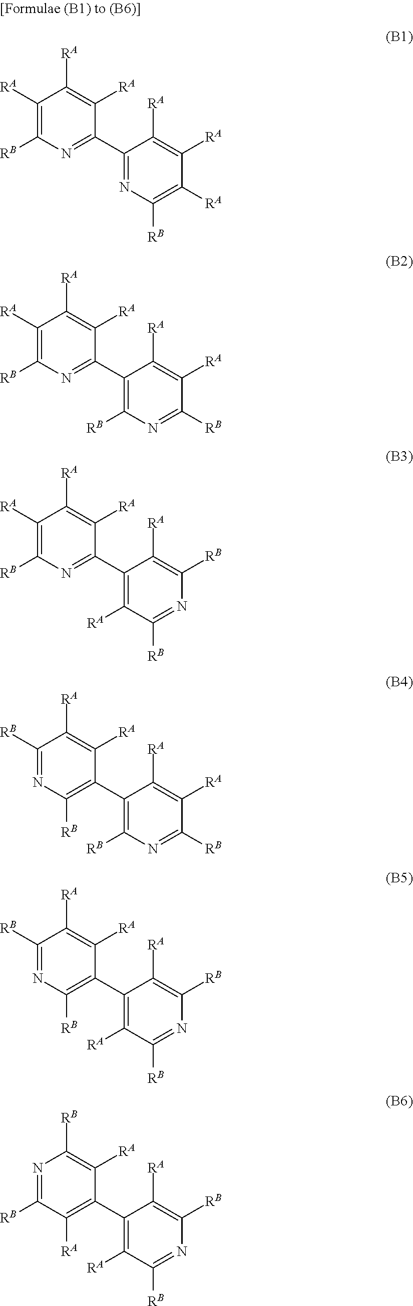
wherein, in Formula 1, a is 1, b is an integer from 0 to 3, c is an integer from 1 to 3,
in Formulae (A1) to (A6) and (B1 to B6), each of R^{A} is independently an alkyl group having 1 to 10 carbon atoms, an aryl group having 6 to 30 carbon atoms, a nitrile group, a hydrogen atom or a halogen atom, and each of R^{B} is independently an alkyl group having 1 to 10 carbon atoms or an aryl group having 6 to 30 carbon atoms, provided that one of R^{A} in the selected indolocarbazole group and one of R^{B} in the selected bipyridine group represents a bonding site with L.

3. The organic electroluminescence device as claimed in claim 2, wherein a molecular weight of the indolocarbazole derivative represented by Formula (1) is less than or equal to 900.

4. The organic electroluminescence device as claimed in claim 2, wherein the indolocarbazole derivative represented by Formula (1) is included in a host material of an emission layer.

5. The organic electroluminescence device as claimed in claim 3, wherein the indolocarbazole derivative represented by Formula (1) is included in a host material of an emission layer.

6. The organic electroluminescence device as claimed in claim 2, wherein the indolocarbazole derivative represented by Formula (1) is included in a stacking layer adjacent to an emission layer between the emission layer and a positive electrode.

7. The organic electroluminescence device as claimed in claim 3, wherein the indolocarbazole derivative represented by Formula (1) is included in a stacking layer adjacent to an emission layer between the emission layer and a positive electrode.

8. The indolocarbazole derivative as claimed in claim 1, being selected from the following Compounds 1 to 20:

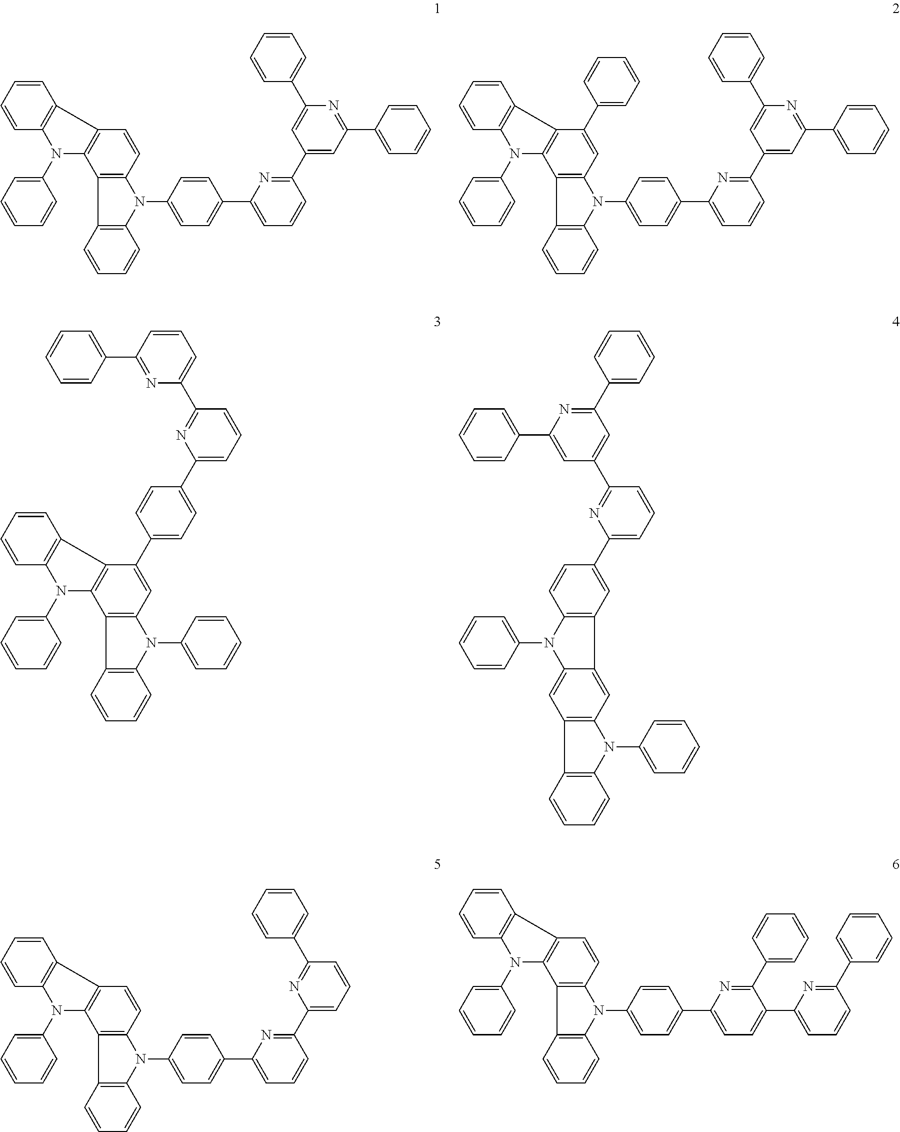

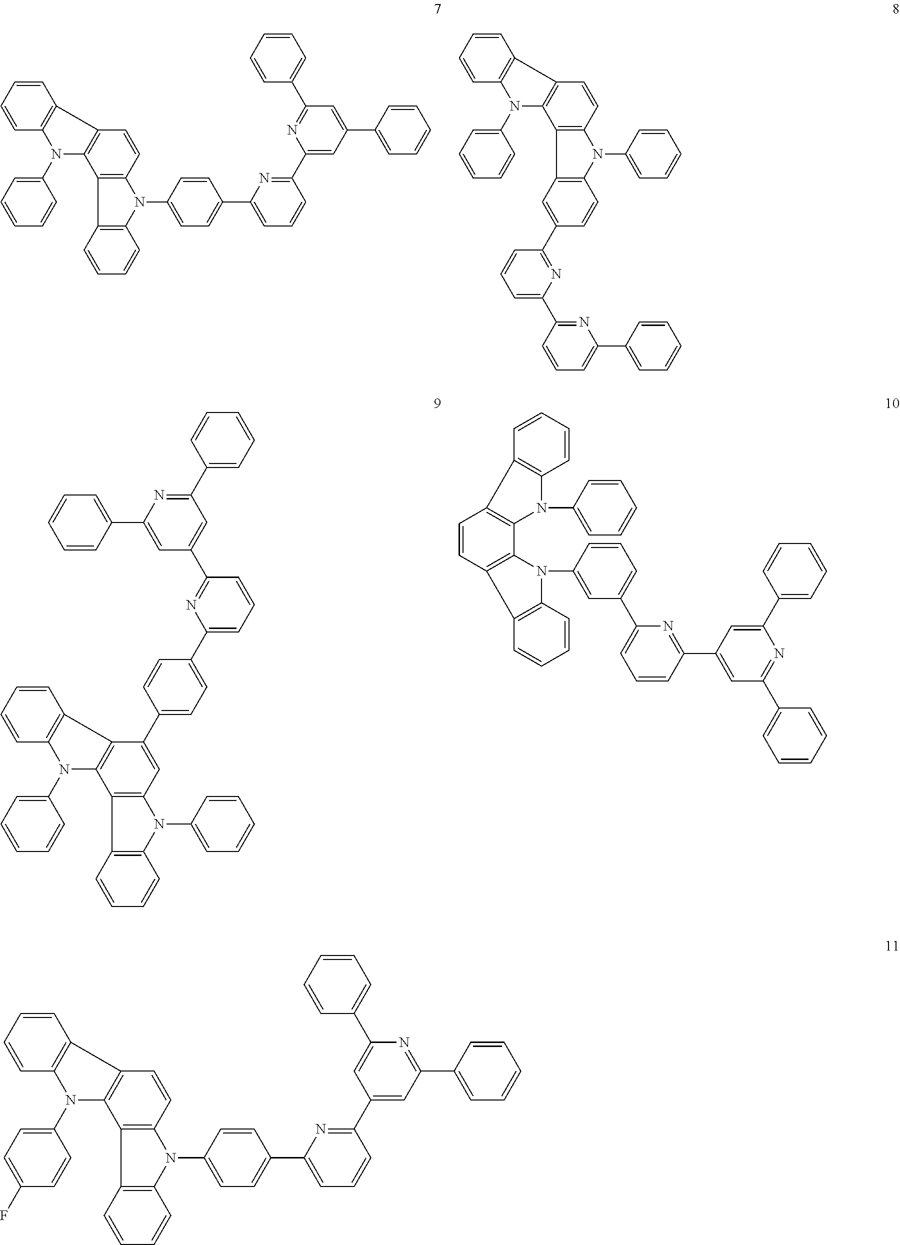

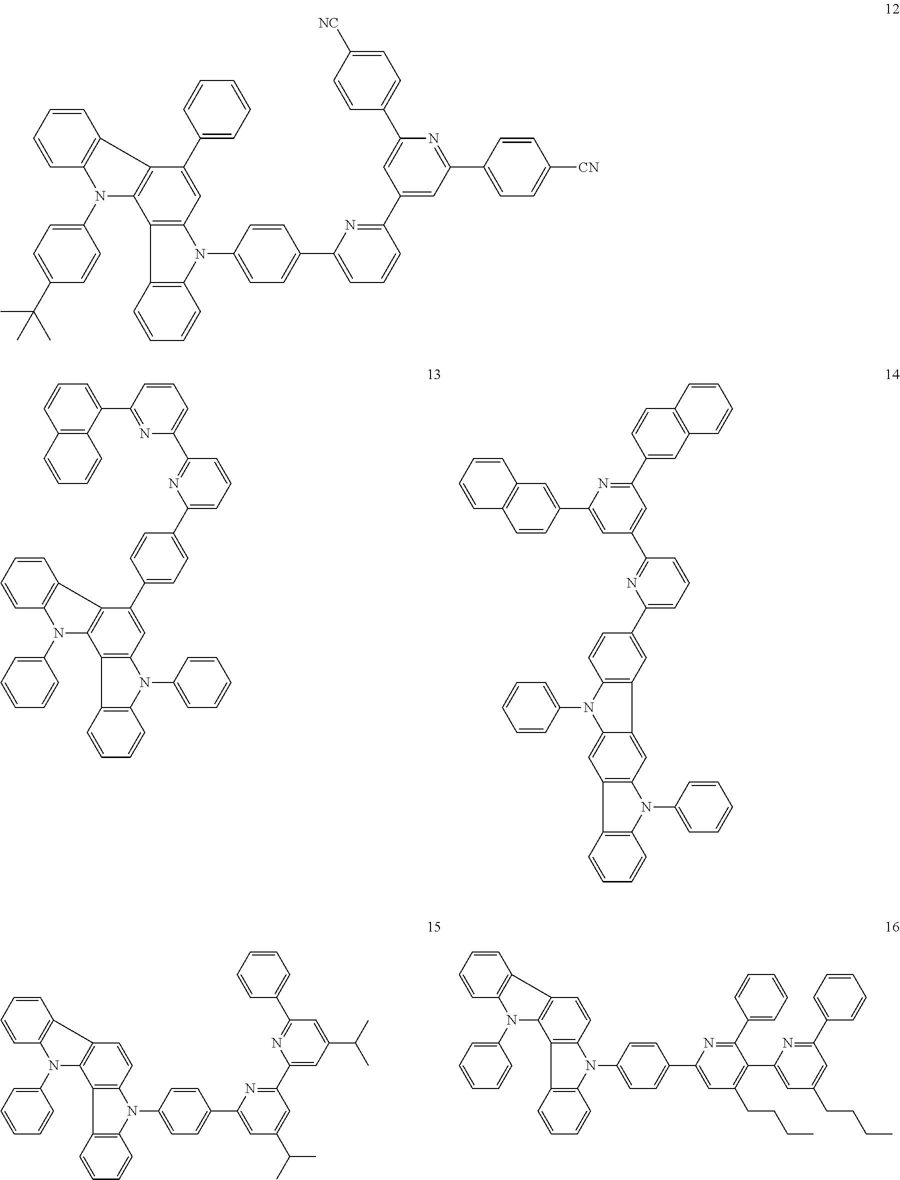

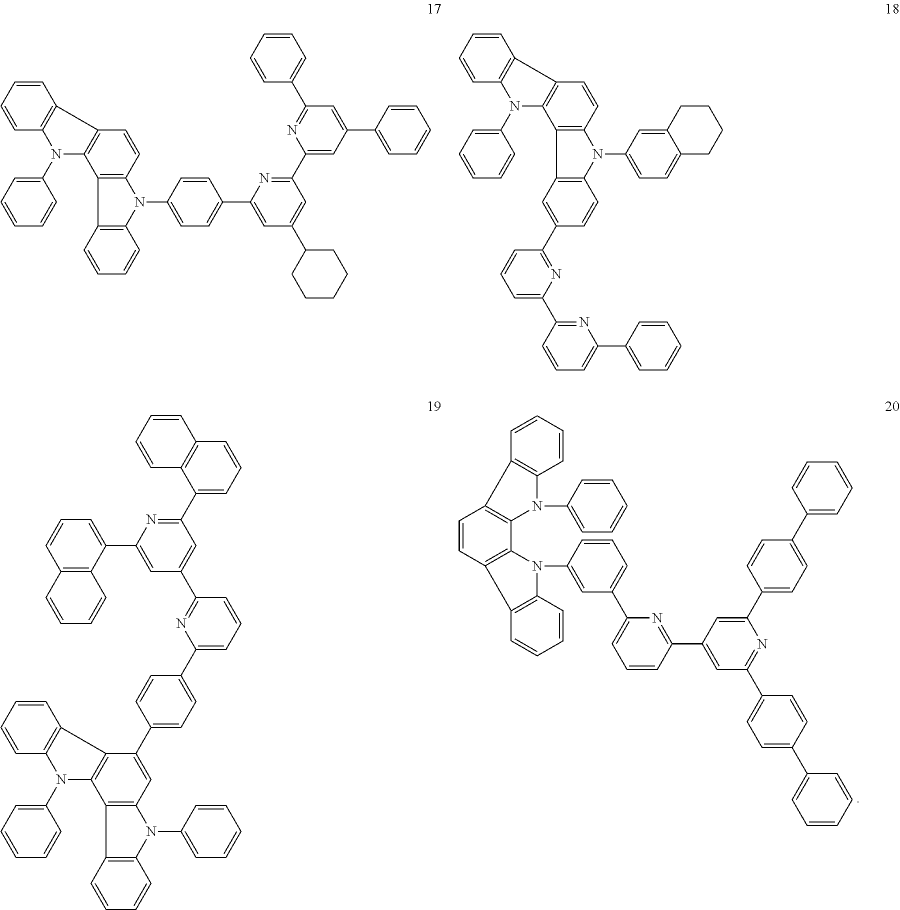

9. The organic electroluminescence device as claimed in claim 2, wherein the indolocarbazole derivative is selected from the following Compounds 1 to 20: 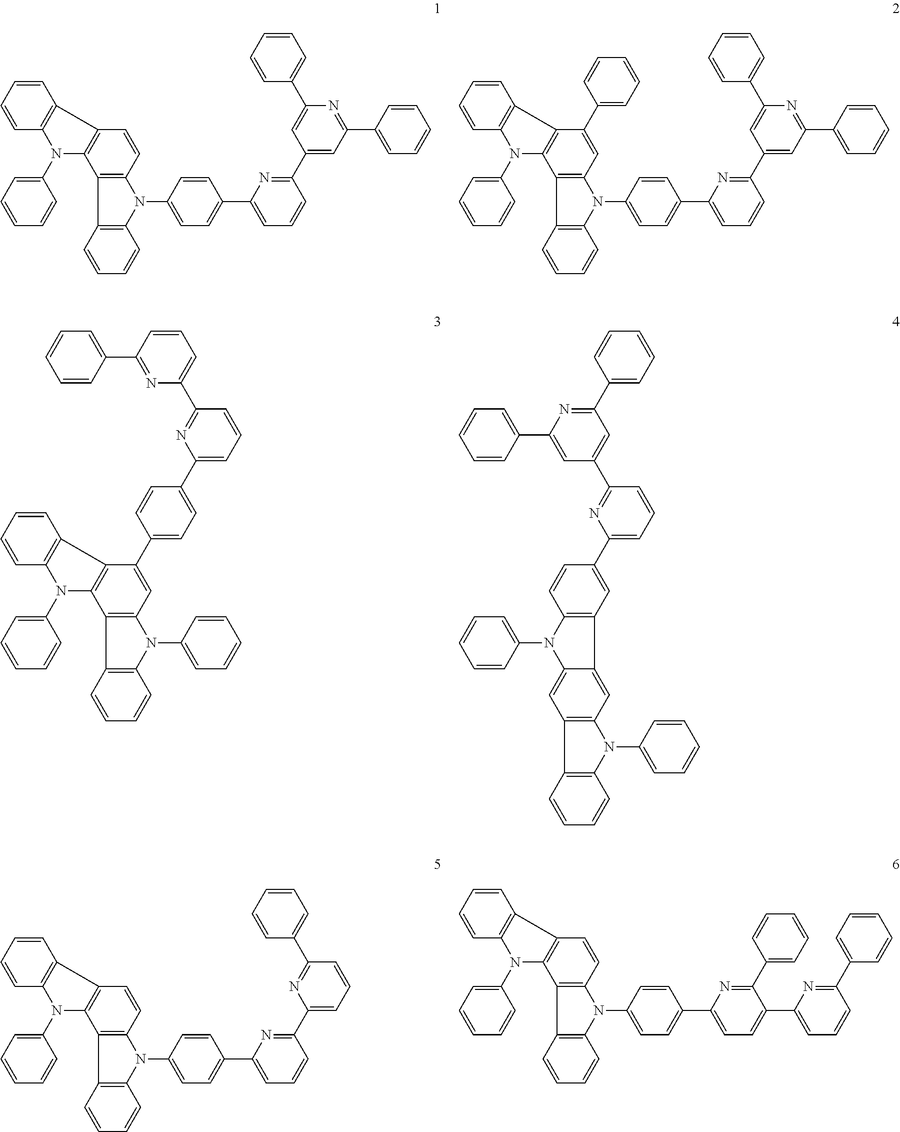 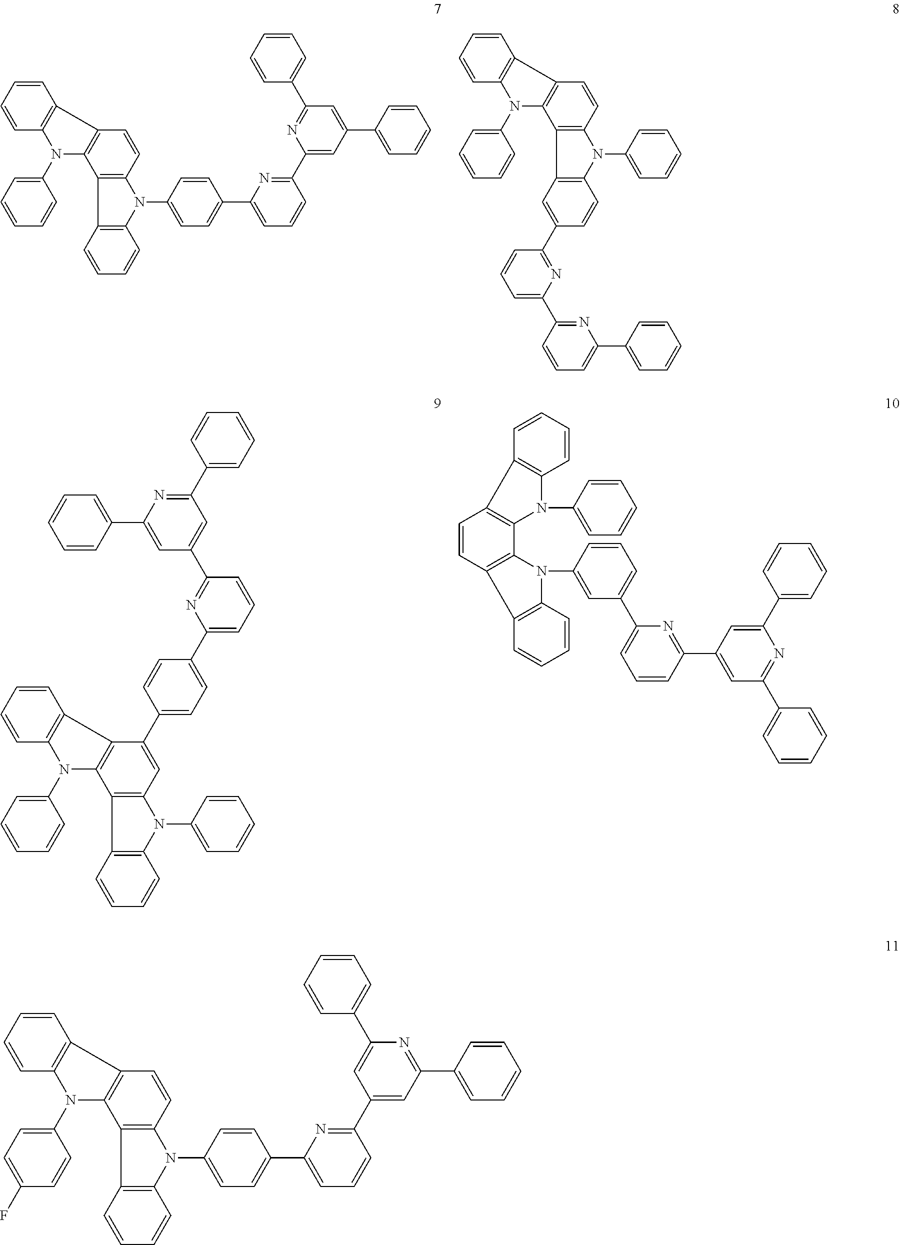 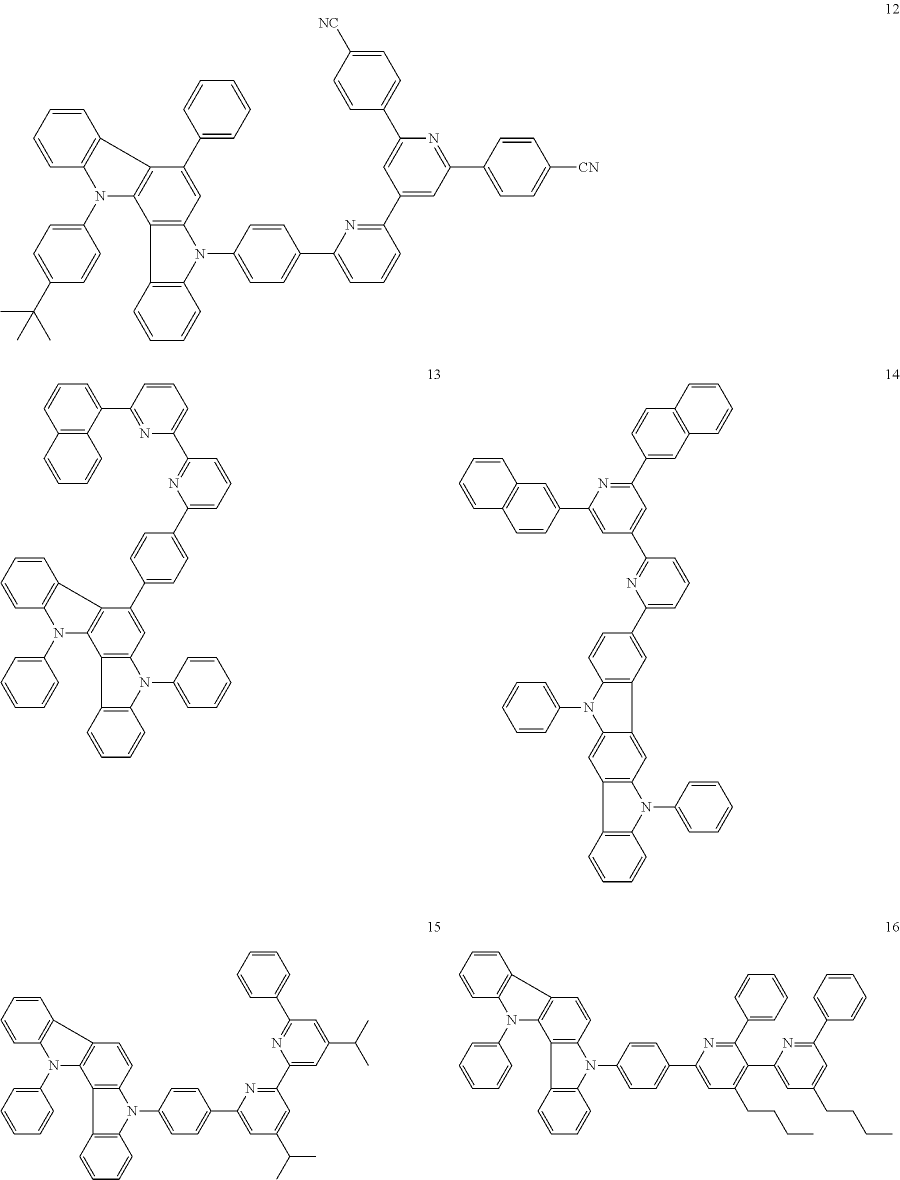 [chemical structure]
